(19) United States
(12) Patent Application Publication
(10) Pub. No.: US 2007/0155112 A1
(43) Pub. Date: Jul. 5, 2007

(54) MOM CAPACITOR

(76) Inventor: Chan Ho Park, Incheon (KR)

Correspondence Address: SHERR & NOURSE, PLLC, 620 HERNDON PARKWAY, SUITE 200, HERNDON, VA, 20170, US

(21) Appl. No.: 11/615,718

(22) Filed: Dec. 22, 2006

(30) Foreign Application Priority Data
Dec. 30, 2005 (KR) 10-2005-0134727

(51) Int. Cl. H01L 21/20

(52) U.S. Cl. 438/386

(57) ABSTRACT

A method of manufacturing a capacitor, which uses metal as a top electrode and a bottom electrode. A plurality of first electrodes may be formed with a plurality of first conductive lines and a plurality of plugs. A plurality of second electrodes may be formed with a plurality of second conductive lines and a plurality of plugs. Oxide layers may be formed between first electrodes and second electrodes. First and second electrodes may be formed such that they intersect each other on every side.

The present application claims priority under 35 U.S.C. 119 and 35 U.S.C. 365 to Korean Patent Application No. 10-2005-0134727 (filed on Dec. 30, 2005), which is hereby incorporated by reference in its entirety.

### BACKGROUND

Merged Memory Logic (MML) are devices which may integrates a memory cell array (e.g. Dynamic Random Access Memory (DRAM)) and an analog or peripheral circuit in one chip. Multimedia extensions may be advanced by MML. MML may require relatively high integration and relatively high speed for some applications.

Analog circuits having relatively high-speed operation may need a capacitor with a relatively large capacitance. A capacitor with a Polysilicon-Insulator-Polysilicon (PIP) structure may cause complications. Conductive polysilicon in a PIP capacitor may be used in a top electrode and a bottom electrode. An oxidation reaction occurred at an interface between a top or bottom electrode and a dielectric thin layer may inadvertently cause an oxide layer to be formed. An inadvertently formed oxide layer may cause the capacitance of a capacitor to be reduced. Capacitance may be reduced due to a depletion region formed in a polysilicon layer. A capacitor with reduced capacitance may be unsuitable for high-speed and high-frequency operation.

A top electrode and a bottom electrode of a capacitor may be a Metal-Insulator-Metal (MIM) structure which uses a metal in a top electrode and in a bottom electrode. A capacitor may have a MIM structure, which may be used in a high performance semiconductor device since it may have relatively low resistivity and substantially no parasitic capacitance caused by depletion.

FIGS. 1A to 1E illustrate a method of forming a MIM capacitor. As illustrated in FIG. 1A, interlayer dielectric layer 2 may be formed, in accordance with embodiments. A metallic conductive layer may be formed and patterned over interlayer dielectric layer 2 to form bottom electrode 4a and bottom interconnection 4b of a capacitor. Interlayer dielectric layer 2a may be formed over a semiconductor substrate.

As illustrated in FIG. 1B, contact hole 8 may expose bottom electrode 4a of a capacitor. Contact hole 8 may be formed using a photolithographic process. Contact hole 8 may expose a surface of bottom electrode 4a. Contact hole 8 may be the effective area. In embodiments, a capacitor may have a relatively large size.

As illustrated in FIG. 1C, dielectric layer 10 may be formed over a semiconductor substrate having the contact hole 8. As illustrated in FIG. 1D, via hole 12 may expose the bottom of interconnection 4b. Via hole 12 may be formed using a photolithographic process.

As illustrated in FIG. 1E, a top interconnecting conductive layer may be formed over semiconductor substrate, in contact hole 8 (e.g. over dielectric layer 10), and in via hole 12. A top interconnecting conductive layer may be patterned to form top electrode 14a and top interconnection 14b of a capacitor.

It may be difficult to apply a MIM capacitor in an analog apparatus that requires high quality and reliability. It may be difficult to apply a MIM capacitor in a relatively highly integrated semiconductor and a high capacity.

### SUMMARY

Embodiments relate to a Metal-Oxide-Metal (MOM) capacitor. In embodiments, a MOM capacitor may be relatively highly integrated and/or may have a relatively high capacitance. In embodiments, a MPM capacitor may be substituted for a MIM capacitor. Embodiments may increase integration of a MOM capacitance by using a minimum design rule with respect to a MOM interconnection.

Embodiments relate to a manufacturing method of a capacitor, which uses metal as a top electrode and a bottom electrode. In embodiments, a plurality of first electrodes may be formed with a plurality of first conductive lines and a plurality of plugs. A plurality of second electrodes may be formed with a plurality of second conductive lines and a plurality of plugs. Oxide layers may be formed between first electrodes and second electrodes. First and second electrodes may be formed such that they intersect each other on every side.

### BRIEF DESCRIPTION OF THE DRAWINGS

FIGS. 1A to 1E illustrate a method of forming a MIM capacitor.

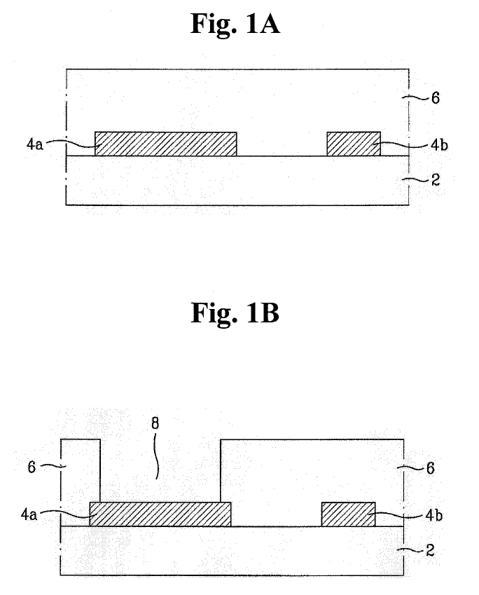

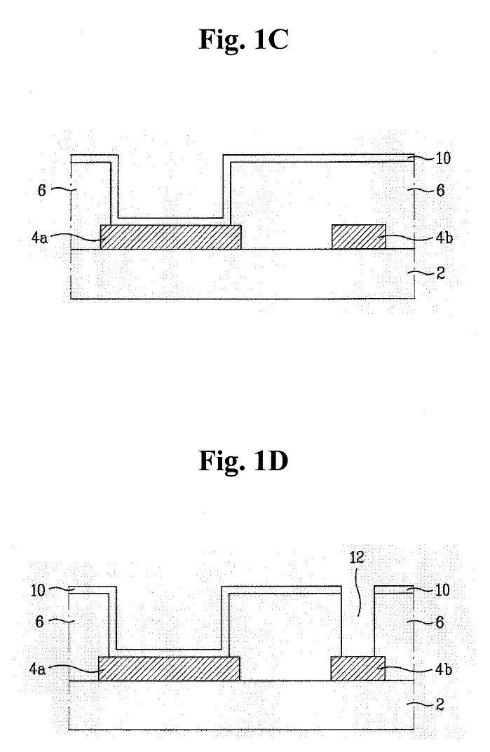

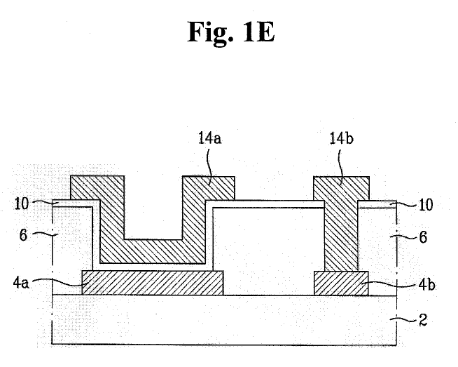

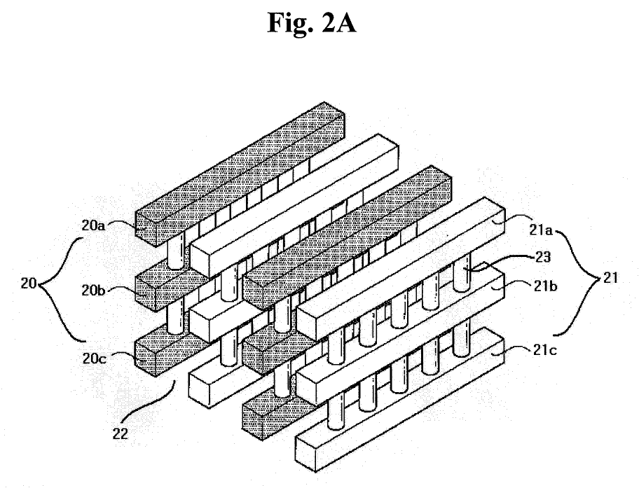

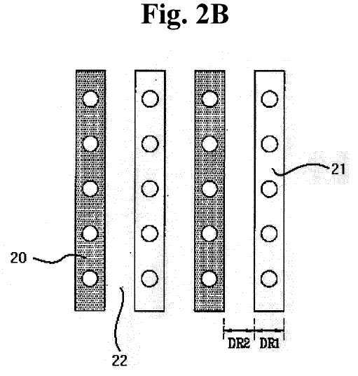

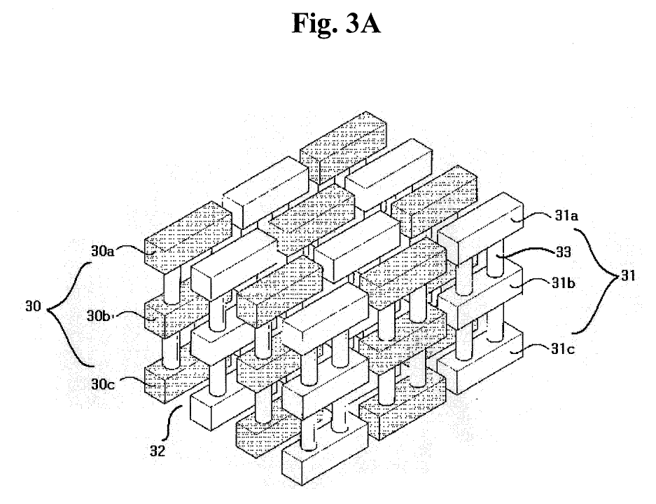

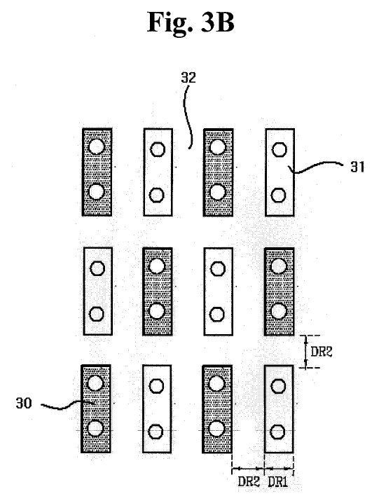

Example FIGS. 2A and 2B illustrate a MOM capacitor, in accordance with embodiments.

Example FIGS. 3A and 3B illustrate a MOM capacitor having relatively high integration, in accordance with embodiments.

### DETAILED DESCRIPTION

As illustrated in FIG. 2A, a MOM capacitor may have a vertical parallel plate type structure. Capacitors of conductive lines 20a to 20c are coupled to each other using plugs 23. Capacitors of conductive lines 21a to 21c are coupled to each other using plugs 23.

In embodiments, MOM capacitors include a plurality of first electrodes 20, a plurality of second electrodes 21, and oxide layers 22. A plurality of first electrodes 20 may have a plurality of first conductive lines 20a to 20c and a plurality of plugs 23, which couple e first conductive lines 20a to 20c. A plurality of plugs 23 may have a rod shape, in accordance with embodiments.

In embodiments, a plurality of plugs 23 may interconnect adjacent conductive lines 20a and 20b or adjacent conductive lines 20b and 20c. In embodiments, a plurality of second electrodes 21 may have a plurality of second conductive lines 21a to 21c and a plurality of plugs 23 which couple second conductive lines 21a to 21c. A plurality of plugs 23 may interconnect adjacent conductive lines 20a and 20b or adjacent conductive lines 20b and 20c. Oxide layers 22 may be formed between a plurality of first electrodes 20 and second electrodes 21.

In embodiments, a plurality of first conductive lines 20a to 20c and a plurality of second conductive lines 21a to 21c may form vertically deposited structures and may have a width of at least approximately 0.30 μm. First or second conductive lines 20a to 20c and/or 21a to 21c may have a width of at least approximately 0.30 μm. First or second conductive lines may have a gap of at least 0.30 μm.

As illustrated in FIG. 2B, first and second electrodes may have a width DR1. Oxide layers may have a width DR2. A relatively high degree of integration of a MOM capacitor may be achieved by widening widths of electrodes 20 and 21 and shortening a length of electrodes 20 and 21.

As illustrated in FIG. 3A, a MOM capacitor may have a vertical parallel plate type structure, in accordance with embodiments. Conductive lines 30a to 30c may be coupled to each other by plugs 33. Conductive lines 31a to 31c may be coupled to each other by plugs 33. In embodiments, a MOM capacitor may include a plurality of first electrodes 30, a plurality of second electrodes 31, and oxide layers 32.

A plurality of first electrodes 30 may have a plurality of first conductive lines 30a to 30c. A plurality of plugs 33 may couple first conductive lines 30a to 30c. A plurality of second electrodes 31 may have a plurality of second conductive lines 31a to 31c and a plurality of plugs 33 for coupling second conductive lines 31a to 31c. Oxide layers 32 may be interposed between first electrodes 30 and second electrodes 31.

A plurality of first conductive lines 30a to 30c and a plurality of second conductive lines 31a to 31c may form vertically deposited structures. A plurality of first conductive lines 30a to 30c and a plurality of second conductive lines 31a to 31c may have a width of at least approximately 0.30 μm. First or second conductive lines 30a to 30c or 31a to 31c may have a gap of at least approximately 0.30 μm. A capacitor may be relatively highly integrated by forming first electrodes 30 and second electrodes 31, such that they intersect each other behind/front and right/left, in accordance with embodiments.

As illustrated in FIG. 3B, first and second electrodes 30 and 31 may have a width DR1. Oxide layers may have a width DR2. In embodiments, integration of MOM capacitors may be relatively high by widening the widths of electrodes and/or shortening the length electrodes.

In 0.18 μm technology, where a Critical Dimension (CD) of a gate electrode may be approximately 0.18 μm, in order for capacitors to have a high degree of integration, first and second electrodes may be formed to have a width (DR1) of at least approximately 0.40 μm and/or oxide layers may be formed to have a width (DR2) of at least approximately 0.30 μm.

In 0.13 μm technology, where a Critical Dimension (CD) of a gate electrode may be approximately 0.13 μm, in order for capacitors to have a relatively high degree of integration, first and second electrodes may be formed to have a width (DR1) of at least approximately 0.30 μm and/or oxide layers may be formed to have a width (DR2) of at least approximately 0.23 μm.

In embodiments, a method of fabricating a MOM capacitor may substitute a method of fabricating a MIM capacitor, which is complex and expensive. In embodiments, a MOM capacitor may be relatively highly integrated by widening the widths of the capacitor electrodes and the oxide layers and shortening their length.

It will be apparent to those skilled in the art that various modifications and variations can be made to embodiments. Thus, it is intended that embodiments cover modifications and variations thereof within the scope of the appended claims.

What is claimed is:

1. A method of forming a capacitor comprising:
forming a plurality of first electrodes, wherein the plurality of first electrodes comprises a plurality of first conductive lines and plugs which couple the first conductive lines;
forming a plurality of second electrodes aligned opposite to the first electrodes, wherein the plurality of second electrodes comprises a plurality of second conductive lines and plugs which couple the second conductive lines; and
forming oxide layers between the first electrodes and the second electrodes.

2. The method of claim 1, wherein the first electrodes and the second electrodes are alternately disposed.

3. The method of claim 1, wherein the plurality of first conductive lines has a vertically deposited structure.

4. The method of claim 1, wherein the plurality of second conductive lines has a vertically deposited structure.

5. The method of claim 1, wherein the first and second conductive lines have a width of at least approximately 0.3 μm.

6. The method of claim 1, wherein the first and second conductive lines have a gap of at least approximately 0.30 μm.

7. The method of claim 1, wherein:
the capacitor is integrated with a transistor having a gate electrode with a critical dimension of approximately 0.18 μm;
a width of the first conductive lines and the second conductive lines is at least approximately 0.30 μm; and
the first conductive lines and the second conductive lines have a width of at least approximately 0.40 μm.

8. The method of claim 1, wherein:
the capacitor is integrated with a transistor having a gate electrode with a critical dimension of approximately 0.13 μm;
a width of the first conductive lines and the second conductive lines is at least approximately 0.23 μm; and
the first conductive lines and the second conductive lines have a width of at least approximately 0.30 μm.

9. The method of claim 1, wherein the capacitor is a metal-oxide-metal capacitor.

10. The method of claim 1, wherein the capacitor is integrated into a merged memory logic device.

11. A capacitor comprising:
a plurality of first electrodes comprising a plurality of first conductive lines and plugs which couple the first conductive lines;
a plurality of second electrodes aligned opposite to the first electrodes comprising a plurality of second conductive lines and plugs which couple the second conductive lines; and
oxide layers formed between the first electrodes and the second electrodes.

12. The capacitor of claim 11, wherein the first electrodes and the second electrodes are alternately disposed.

13. The capacitor of claim 11, wherein the plurality of first conductive lines has a vertically deposited structure.

14. The capacitor of claim 11, wherein the plurality of second conductive lines has a vertically deposited structure.

15. The capacitor of claim 11, wherein the first and second conductive lines have a width of at least approximately 0.3 μm.

16. The capacitor of claim 11, wherein the first and second conductive lines have a gap of at least approximately 0.30 μm.

17. The capacitor of claim 11, wherein:
the capacitor is integrated with a transistor having a gate electrode with a critical dimension of approximately 0.18 μm;
a width of the first conductive lines and the second conductive lines is at least approximately 0.30 μm; and
the first conductive lines and the second conductive lines have a width of at least approximately 0.40 μm.

18. The capacitor of claim 11, wherein:
the capacitor is integrated with a transistor having a gate electrode with a critical dimension of approximately 0.13 μm;
a width of the first conductive lines and the second conductive lines is at least approximately 0.23 μm; and
the first conductive lines and the second conductive lines have a width of at least approximately 0.30 μm.

19. The capacitor of claim 11, wherein the capacitor is a metal-oxide-metal capacitor.

20. The capacitor of claim 11, wherein the capacitor is integrated into a merged memory logic device.
